(19) United States
(12) Patent Application Publication
(10) Pub. No.: US 2006/0197201 A1
(43) Pub. Date: Sep. 7, 2006

(54) Image sensor structure

(76) Inventor: Chung Hsien Hsin, Hsinchu Hsien (TW)

Correspondence Address: PRO-TECTOR INTERNATIONAL SERVICES, 20775 NORADA CT., SARATOGA, CA, 95070, US

(21) Appl. No.: 11/066,527

(22) Filed: Feb. 23, 2005

(51) Int. Cl. H01L 23/02

(52) U.S. Cl. 257/678

(57) ABSTRACT

An image sensor structure includes a substrate, a photosensitive chip, a plurality wires, a plurality of ball elements, a transparent layer, and a glue layer. The substrate has an upper surface and a lower surface. The photosensitive chip has a plurality of bonding pads, and is mounted on the upper surface of the substrate. The plurality of wires are electrically connected the bonding pads of the photosensitive chip to the substrate. The plurality of ball elements is located on the bonding pads of the photosensitive chip. The transparent layer is mounted on the ball elements to encapsulate the photosensitive chip. The glue layer is surrounded on the periphery of the upper surface of the substrate for encapsulating the wires, and is fixed the transparent layer.

### BACKGROUND OF THE INVENTION

1. Field of the invention

The invention relates to an image sensor structure, and in particular to an image sensor structure is capable of manufacturing to be light, thin, and small.

2. Description of the Related Art

Referring to FIG. 1, it is a conventional image sensor structure includes a substrate 10, a frame layer 18, a photosensitive chip 26, a plurality of wires 28, and a transparent layer 34.

The substrate 10 has a first surface 12 on which plurality of first electrodes 15 are formed, and a second surface 14 on which plurality of second electrodes 16 are formed. The first electrodes 15 are corresponding to electrically connect to the second electrodes 16 by the conductive wires 17, which are located at the side of the substrate. The frame layer 18 has an upper surface 20 and a lower surface 22 adhered to the first surface 12 of the substrate 10 to form a chamber 24 together with the substrate 10. The photosensitive chip 26 is arranged within the chamber 24, and is mounted to the first surface 12 of the substrate 10. Each wire 28 has a first terminal 30 and a second terminal 32. The first terminals 30 are electrically connected to the photosensitive chip 26, and the second terminals 32 are electrically connected to the first electrodes 15 of the substrate 10. The transparent layer 34 is adhered to the upper surface 20 of the frame layer 18.

Accordingly, when the photosensitive chip 20 has a large scale, it is inconvenient, or even impossible, in the manufacturing processes for bonding and electrically connecting wires to the first electrodes 16 of the substrate 10. Therefore, the size of the substrate 10 has to be large so as to increase the space for wire bonding.

### SUMMARY OF THE INVENTION

An objective of the invention is to provide an image sensor structure, that is ease to be package and capable of reducing the volume of the structure and the manufacturing cost.

Another objective of the invention is to provide an image sensor structure capable of packaging image sensor chip having different sizes without changing the package volume. The objective of the producing packages having the same volume can be achieved.

To achieve the above-mentioned object, the invention provides an image sensor structure includes a substrate, a photosensitive chip, a plurality wires, a plurality of ball elements, a transparent layer, and a glue layer. The substrate has an upper surface and a lower surface. The photosensitive chip has a plurality of bonding pads, and is mounted on the upper surface of the substrate. The plurality of wires are electrically connected the bonding pads of the photosensitive chip to the substrate. The plurality of ball elements is located on the bonding pads of the photosensitive chip. The transparent layer is mounted on the ball elements to encapsulate the photosensitive chip. The glue layer is surrounded on the periphery of the upper surface of the substrate for encapsulating the wires, and is fixed the transparent layer.

### BRIEF DESCRIPTION OF THE DRAWINGS

FIG. 1 is a cross-sectional view showing a conventional image sensor structure.

FIG. 2 is a first schematic illustration showing an image sensor structure of the present invention.

FIG. 3 is a second schematic illustration showing an image sensor structure without glue layer.

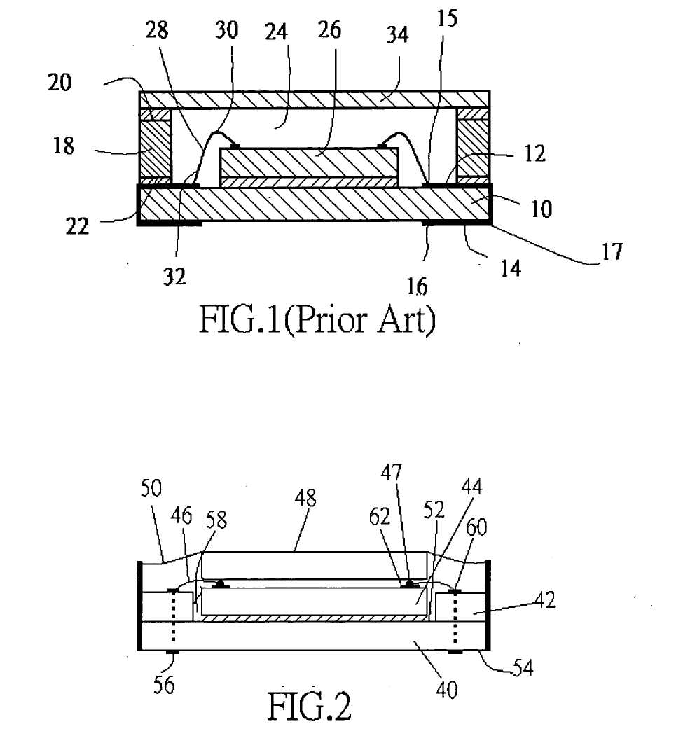

### DETAILED DESCRIPTION OF THE INVENTION

Please refer to FIG. 2, an image sensor structure of the present invention includes a substrate 40, a frame layer 42, a photosensitive chip 44, a plurality of wires 46, a plurality of ball elements 47, a transparent layer 48, and a glue layer 50.

The substrate 40 has an upper surface 52, and a lower surface 54 on which first electrodes 56 are formed.

The frame layer 42 is mounted on the upper surface 52 of the substrate 40 so as to define a cavity 58 by the frame layer 42 and the substrate 40. The frame layer 42 has second electrodes 60 electrically connected to correspond of the first electrodes 56.

The photosensitive chip 44, which a plurality of bonding pads 62 are formed, is mounted on the upper surface 52 of the substrate 40 and is located within the cavity 58.

The plurality of wires 46 are electrically connected the bonding pads 62 of the photosensitive chip 44 to correspond to the second electrodes 60 of the frame layer 42. The wires 46 are bonded from the second electrodes 60 of the frame layer 42 to the bonding pads 62 of the photosensitive chip 44, so as to the wires 46 are flat.

The plurality of ball elements 47 are metal ball, are located on the each bonding pads 62 of the photosensitive chip 44.

The transparent layer 48 is mounted on the ball elements 47 to encapsulate the photosensitive chip 44. And The glue layer 50 is surrounded on the periphery of the upper surface 52 of the substrate 40 for encapsulating the wires 46, and is fixed the transparent layer 48.

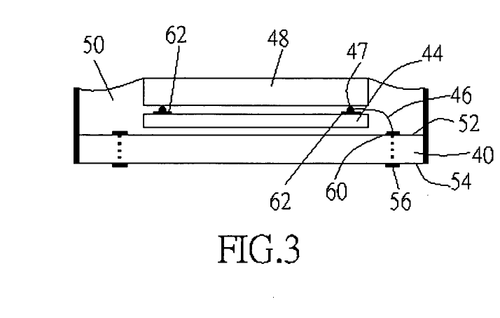

Please refer to FIG. 3, an image sensor structure of the present invention includes a substrate 40, a photosensitive chip 44, a plurality of wires 46, a plurality of ball elements 47, a transparent layer 48, and a glue layer 50.

The substrate 40 has an upper surface 52 on which second electrodes 60 are formed, and a lower surface 54 on which first electrodes 56 are formed.

The photosensitive chip 44, which a plurality of bonding pads 62 are formed, is mounted on the upper surface 52 of the substrate 40.

The plurality of wires 46 are electrically connected the bonding pads 62 of the photosensitive chip 44 to correspond to the second electrodes 60 of the substrate 40. The wires 46 are bonded from the second electrodes 60 of the substrate 40 to the bonding pads 62 of the photosensitive chip 44, so as to the wires 46 are flat.

The plurality of ball elements 47 are metal ball, are located on the each bonding pads 62 of the photosensitive chip 44.

The transparent layer 48 is mounted on the ball elements 47 to encapsulate the photosensitive chip 44. And The glue layer 50 is surrounded on the periphery of the upper surface 52 of the substrate 40 for encapsulating the wires 46, and is fixed the transparent layer 48.

Therefore, it is possible to select the substrate 40 having a smaller size to package the photosensitive chip 44 having the same original size. Thus, it is possible to obtain an image sensor structure having smaller volume.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. An image sensor structure, the structure comprising:
a substrate having an upper surface on which second electrodes are formed, and a lower surface on which first electrodes are formed;
a photosensitive chip, which a plurality of bonding pads are formed, mounted on the upper surface of the substrate
a plurality of wires electrically connected the bonding pads of the photosensitive chip to correspond to the second electrodes of the substrate;
a plurality of ball elements located on the bonding pads of the photosensitive chip
a transparent layer mounted on the ball elements to encapsulate the photosensitive chip; and
a glue layer surrounded on the periphery of the upper surface of the substrate for encapsulating the wires, and fixed the transparent layer.

2. The image sensor structure according to claim 1, wherein the balls elements are formed of metal ball.

3. The image sensor structure according to claim 2, wherein the transparent layer is transparent glass.

4. The image sensor structure according to claim 1, wherein the upper surface of the substrate is formed with a frame layer, the second electrodes are formed on the frame layer.
